(19) United States
(12) Patent Application Publication
(10) Pub. No.: US 2025/0059025 A1
(43) Pub. Date: Feb. 20, 2025

(54) METHOD FOR DETECTING CONTAMINATION OF A MEMS SENSOR

(71) Applicant: Robert Bosch GmbH, Stuttgart (DE)

(72) Inventors: Martin Kittel, Stuttgart (DE); Joachim Kreutzer, Stuttgart (DE); Tamas Dogei, Nagykata (HU)

(21) Appl. No.: 18/789,780

(22) Filed: Jul. 31, 2024

(30) Foreign Application Priority Data
Aug. 18, 2023 (DE) 10 2023 207 927.5

(51) Int. Cl. B81B 7/00; B81C 99/00

(52) U.S. Cl. CPC B81B 7/0087; B81C 99/0045; B81B 2201/02; B81B 2207/03; B81B 2207/115

(57) ABSTRACT

A method for detecting contamination of a micro-electromechanical sensor of a sensor module using a heater, wherein the sensor module has a temperature sensor arranged at a distance from the heater and from the micro-electromechanical sensor. The heater heats the sensor, which is measured by the temperature sensor. The sensor measures physical quantities at different times. The measured physical quantities are compensated based on the temperatures measured at the different times. It is ascertained based on the compensated physical quantities and the temperature difference between the different times whether the micro-electromechanical sensor is free of contamination or has contamination. A system for detecting contamination of a micro-electromechanical sensor of a sensor module, a computer program and a machine-readable storage medium, are also described.

### CROSS REFERENCE

The present application claims the benefit under 35 U.S.C. § 119 of German Patent Application No. DE 10 2023 200.5 filed on Aug. 18, 2023, which is expressly incorporated herein by reference in its entirety.

### FIELD

The present invention relates to a method for detecting contamination of a micro-electromechanical sensor, a system for detecting contamination of a micro-electromechanical sensor, a computer program and a machine-readable storage medium.

### BACKGROUND INFORMATION

German Patent Application No. DE 10 2020 203 910 B3 describes a method for detecting contamination of a MEMS sensor element SUMMARY

An object of the present invention is to provide a concept for detecting contamination of a micro-electromechanical sensor of a sensor module.

This object may be achieved by means of features of the present invention. Advantageous example embodiments of the present invention are disclosed herein.

According to a first aspect of the present invention, a method is provided for detecting contamination of a micro-electromechanical sensor of a sensor module using a heater, wherein the sensor module has a temperature sensor arranged at a distance from the heater and the micro-electromechanical sensor.

According to an example embodiment of the present invention, the method comprises the following steps:

Outputting control signals for controlling the heater so that the heater generates thermal energy to heat the micro-electromechanical sensor;
receiving sensor output signals representing physical quantities measured by the micro-electromechanical sensor at different times during the generation of thermal energy by the heater, and temperature sensor output signals representing temperatures measured by the temperature sensor at different times during the generation of thermal energy by the heater;
compensating the sensor output signals on the basis of the temperature sensor output signals in order to generate compensated sensor output signals representing the compensated physical quantities measured at the different times;
ascertaining on the basis of the compensated sensor output signals and the temperature sensor output signals whether the micro-electromechanical sensor is free of contamination or has contamination.

According to a second aspect of the present invention, a system for detecting contamination of a micro-electromechanical sensor of a sensor module is provided. According to an example embodiment of the present invention, the system comprises:
a heater and
a sensor module, the sensor module comprising:
a micro-electromechanical sensor and
a temperature sensor arranged at a distance from the heater and from the micro-electromechanical sensor,
wherein the system is set up to carry out all steps of the method according to the first aspect.

According to a third aspect of the present invention, a computer program is provided which comprises instructions which, when the computer program is executed by a computer, for example by the system according to the second aspect, cause said computer to carry out a method according to the first aspect of the present invention.

According to a fourth aspect of the present invention, a machine-readable storage medium is provided on which the computer program according to the third aspect of the present invention is stored.

The present invention is based on and includes the finding that the above object may be achieved by heating the micro-electromechanical sensor by means of a heater. In other words, the heating causes a temperature change in the sensor. A temperature is measured by the temperature sensor at different times, wherein physical quantities are measured by the sensor at the different times. Not only measured temperatures but also measured physical quantities are thus available at the different times. On the basis of this information, it is ascertained whether the sensor is contaminated or not. In detail, it is intended that the sensor output signals are compensated on the basis of the temperature sensor output signals. The compensated sensor output signals represent the compensated physical quantities measured at the different times. This therefore means that the measured physical quantities are compensated on the basis of the correspondingly measured temperatures. On the basis of the compensated physical quantities and on the basis of the corresponding measured temperatures, it is ascertained whether the micro-electromechanical sensor is free of contamination or has contamination.

The present invention is based on the finding that contamination of the micro-electromechanical sensor leads to a temperature behavior different from when there is no contamination. This means that with the same heating by the heater, the micro-electromechanical sensor shows or has a different temperature behavior compared to the case in which the micro-electromechanical sensor is free of contamination. One reason for this is in particular that in the case of contamination the micro-electromechanical sensor together with the contamination has a different heat capacity than without contamination.

In other words, a temperature difference or a temperature gradient between sensor and temperature sensor increases when the sensor is contaminated compared to the case in which the sensor is free of contamination. This means that a temperature gradient between sensor and temperature sensor is less when the sensor is free of contamination than when the sensor has contamination.

A specific temperature compensation of the sensor is usually defined for a sensor that is free of contamination. This means that if the sensor has contamination, the specific temperature compensation will no longer work correctly. For example, if a change in the sensor output signal over an absolute temperature difference is compared with a specified change over a comparable temperature range, it will be possible to efficiently determine whether contamination is present or not.

In this way, contamination of a micro-electromechanical sensor can be efficiently detected.

In one example embodiment of the method of the present invention, it is provided that ascertaining whether the micro-electromechanical sensor is free of contamination or has contamination is carried out on the basis of a change in the compensated sensor output signals in relation to a change in the temperature sensor output signals.

This results, for example, in the technical advantage that ascertaining whether the micro-electromechanical sensor is free of contamination or not can be carried out efficiently.

According to this example embodiment of the present invention, it is therefore provided that the change in the measured physical quantities in relation to a change in the measured temperatures is analyzed in order to detect contamination on the basis of a result of the analysis.

In one example embodiment of the method of the present invention, it is provided that the change in the compensated sensor output signals is correlated with the change in the temperature sensor output signals, in particular divided, in order to ascertain a correlated, in particular relative, change in the compensated sensor output signal, wherein, on the basis of the correlated change in the compensated sensor output signal, it is ascertained whether the micro-electromechanical sensor is free of contamination or has contamination.

This results, for example, in the technical advantage that it can be efficiently ascertained whether the micro-electromechanical sensor is free of contamination or has contamination.

For example, correlating involves dividing the change in the compensated sensor output signals by the change in the temperature sensor output signals in order to ascertain a relative change in the compensated sensor output signal. For example, on the basis of the relative change in the compensated sensor output signal, it is ascertained whether the micro-electromechanical sensor is free of contamination or has contamination.

In one example embodiment of the method of the present invention, it is provided that the correlated, in particular relative, change in the compensated sensor output signal is compared with a predetermined change threshold value, wherein, on the basis of the comparison, it is ascertained whether the micro-electromechanical sensor is free of contamination or has contamination.

This results, for example, in the technical advantage that it can be efficiently ascertained whether the micro-electromechanical sensor has contamination or not.

For example, it is determined that the sensor has contamination if the correlated, in particular relative, change in the compensated sensor output signal is greater than or greater than or equal to the predetermined change threshold value. Otherwise, it will be determined, for example, that the micro-electromechanical sensor is free of contamination.

In one example embodiment of the method of the present invention, it is provided that after a target temperature and/or a target temperature difference relative to a temperature for starting the heating is reached, control signals for controlling the heater are output so that the heater stops generating thermal energy for heating the micro-electromechanical sensor.

This results, for example, in the technical advantage that thermal energy is not consumed unnecessarily.

In one example embodiment of the method of the present invention, it is provided that a calibration process is carried out when the micro-electromechanical sensor element is free of contamination, wherein the calibration process comprises control signals being output for controlling the heater so that the heater generates thermal energy to heat the micro-electromechanical sensor, and wherein the calibration process comprises sensor output signals being received which represent physical quantities measured by the micro-electromechanical sensor at different times during the generation of the thermal energy by the heater, and temperature sensor output signals being received which represent temperatures measured by the temperature sensor at the different times during the generation of the thermal energy by the heater, and wherein the calibration process comprises the sensor output signals being compensated on the basis of the temperature sensor output signals in order to generate compensated sensor output signals which represent the compensated physical quantities measured at the different times, and wherein the calibration process comprises the sensor output signals being compensated on the basis of the temperature sensor output signals in order to generate compensated sensor output signals which represent the compensated physical quantities measured at the different times, and wherein the calibration process comprises ascertaining one or more calibration parameters on the basis of the compensated sensor output signals and the temperature sensor output signals, on the basis of which it is ascertained at a time after the calibration process has been carried out whether the micro-electromechanical sensor is free of contamination or has contamination.

This results, for example, in the technical advantage that calibration parameters can be efficiently ascertained, on the basis of which it can be ascertained at a later point in time whether the sensor is free of contamination or not.

In one example embodiment of the method of the present invention, it is provided that the calibration process comprises the change in the compensated sensor output signals being correlated with the change in the temperature sensor output signals, in particular divided, in order to ascertain a correlated, in particular relative, change in the compensated sensor output signal, wherein the calibration process comprises the correlated change in the compensated sensor output signal being set as the predetermined threshold value as one of the one or more calibration parameters.

This results, for example, in the technical advantage that the predetermined threshold value can be set efficiently.

In one example embodiment of the system of the present invention, it is configured in such a way that a first temperature gradient, when the heater is switched on and when the micro-electromechanical sensor is free of contamination, between the temperature sensor and the micro-electromechanical sensor is smaller by at least a predetermined factor than a second temperature gradient, when the heater is switched on and when a micro-electromechanical sensor has contamination, between the temperature sensor and the micro-electromechanical sensor.

This results, for example, in the technical advantage that it can be efficiently ascertained whether the micro-electromechanical sensor is free of contamination or not.

In one example embodiment of the system of the present invention, it is provided that the predetermined factor lies in the closed interval from 10 to 100.

This results, for example, in the technical advantage that the temperature gradient when contamination is present is so much greater compared to a temperature gradient in the absence of contamination that the contamination can be detected efficiently.

In one example embodiment of the system of the present invention, it is provided that the micro-electromechanical sensor is covered with a protective layer having a thickness that lies in the closed interval from 1 μm to 100 μm.

This results, for example, in the technical advantage that the sensor can be protected efficiently.

A protective layer within the meaning of the description includes, for example, a gel. The protective layer is, for example, a gel layer.

Contamination can therefore, for example, settle on the gel or on the gel layer.

The wording that the sensor is free of contamination includes in particular that the gel or the gel layer is free of contamination.

The wording that the sensor has contamination includes in particular that the gel or the gel layer has contamination.

In one example embodiment of the present invention, the system comprises a first substrate having an electronic circuit, in particular a first wafer, in particular an Si wafer.

In one example embodiment of the system of the present invention, it is provided that the micro-electromechanical sensor is comprised by a second substrate, in particular a second wafer, in particular an Si wafer, wherein the second substrate is arranged at a distance from the first substrate and is materially bonded thereto by an adhesive.

This results, for example, in the technical advantage that a unit is created consisting of a sensor and an electronic circuit.

In one example embodiment of the system of the present invention, the first substrate comprises the micro-electromechanical sensor.

This results, for example, in the technical advantage that only one substrate is required to carry, implement or arrange not only the electronic circuit but also the sensor.

In one example embodiment of the system of the present invention, it is provided that the first substrate comprises the temperature sensor.

This results, for example, in the technical advantage that the first substrate can be used efficiently in that it carries not only the temperature sensor but also the electronic circuit.

In one example embodiment of the system of the present invention, it comprises a housing with a base on which the first substrate is arranged, wherein the housing is filled with a protective material such that the micro-electromechanical sensor is covered with the one protective layer.

This results, for example, in the technical advantage that the sensor can be protected efficiently.

Statements made in connection with the system of the present invention apply analogously to the method and vice versa. This means that method features arise directly from system features and vice versa.

The method according to the first aspect of the present invention is carried out, for example, by means of the system according to the second aspect of the present invention.

The sensor of the system according to the second aspect of the present invention is, for example, the sensor as used in connection with the method according to the first aspect.

A substrate in the sense of the description is, for example, a silicon wafer, i.e., an Si wafer.

A sensor within the meaning of the description is a micro-electromechanical one, even if the wording “micro-electromechanical” is not explicitly used.

A sensor within the meaning of the description is, for example, one of the following sensors: pressure sensor, gas sensor, voltage sensor, current sensor, resistance sensor, image sensor, video sensor, lidar sensor, ultrasonic sensor, magnetic field sensor, infrared sensor, radar sensor and temperature sensor.

A contamination within the meaning of the description includes, for example, a fluid body and/or a dust body and/or a solid body and/or a biofilm.

A fluid includes, for example, water and/or one or more other liquids.

For the term “micro-electromechanical,” for example, the abbreviation “MEMS” can be used.

For example, the system is programmed to execute the computer program according to the third aspect.

The method according to the first aspect of the present invention is, for example, a computer-implemented method.

The embodiments and exemplary embodiments of the present invention described here can be combined with one another in any way even if this is not explicitly described.

The heater, for example, is included in the sensor module. The heating, for example, is not detected by the sensor module. This means that the heater can be located, for example, outside the sensor module, i.e. externally.

For example, an electronic circuit is provided, for example the electronic circuit described above. Such an electronic circuit can, for example, be included in the sensor module. The electronic circuit is, for example, configured to receive the sensor output signals and/or the temperature sensor output signals. For example, the electronic circuit is configured to compensate the sensor output signals on the basis of the temperature sensor output signals in order to generate compensated sensor output signals. In other words, the electronic circuit is, for example, configured to perform the compensation step.

For example, an evaluation unit arranged externally in relation to the sensor module is provided, which is configured to compensate the sensor output signals on the basis of the temperature sensor output signals in order to generate compensated sensor output signals. In other words, compensation of the sensor output signals can also take place externally to the sensor module. For example, the electronic circuit is configured to receive the temperature sensor output signals and the sensor output signals and forward them to the external evaluation unit.

Ascertaining whether the micro-electromechanical sensor is free of contamination or has contamination can thus be carried out, for example, by the electronic circuit and/or by the external evaluation unit.

For example, the electronic circuit is configured to output, and in particular to generate, the control signals for controlling the heater.

For example, a control device external to the control module is provided, which is configured to output, and in particular to generate, the control signals for controlling the heater.

The step of generating the control signals, for example, is explicitly included in the method.

Such a control device is, for example, included in the system. Such an evaluation unit is, for example, included in the system.

The electronic circuit is, for example, implemented as an ASIC. Here, ASIC stands for application-specific integrated circuit.

The present invention is explained in more detail below using preferred exemplary embodiments.

### BRIEF DESCRIPTION OF THE DRAWINGS

FIG. 1 shows a flow chart of an example method according to the first aspect of the present invention.

FIG. 2 shows an example system according to the second aspect of the present invention.

FIG. 3 shows an example machine-readable storage medium according to the fourth aspect of the present invention.

FIG. 4 shows a sensor module according to an example embodiment of the present invention.

FIG. 5 shows a flow chart of a further example method according to the first aspect of the present invention.

FIG. 6 shows a first graph.

FIG. 7 shows a second graph.

### DETAILED DESCRIPTION OF EXAMPLE EMBODIMENTS

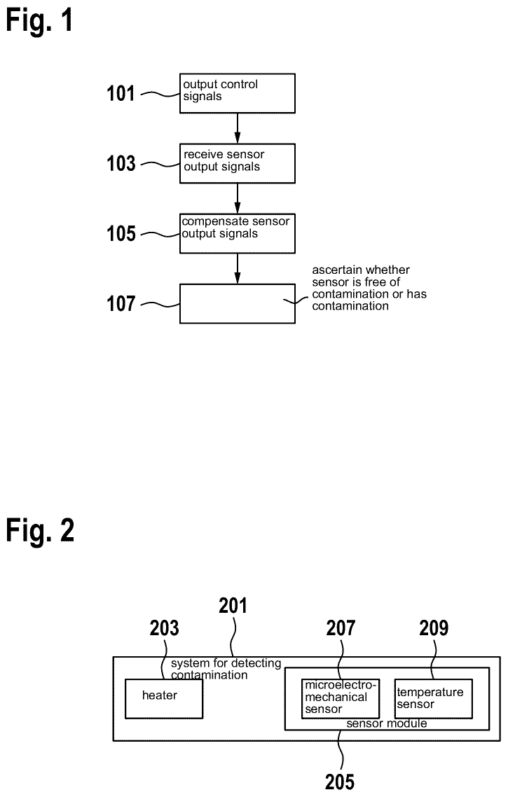

FIG. 1 shows a flow chart of a method for detecting contamination of a micro-electromechanical sensor of a sensor module using a heater, wherein the sensor module has a temperature sensor arranged at a distance from the heater and from the micro-electromechanical sensor, the method comprising the following steps:

Outputting 101 control signals for controlling the heater so that the heater generates thermal energy to heat the micro-electromechanical sensor;
receiving 103 sensor output signals representing physical quantities measured by the micro-electromechanical sensor at different times during the generation of the thermal energy by the heater, and temperature sensor output signals representing temperatures measured by the temperature sensor at the different times during the generation of the thermal energy by the heater;
compensating 105 the sensor output signals on the basis of the temperature sensor output signals in order to generate compensated sensor output signals representing the compensated physical quantities measured at the different times;
ascertaining 107 on the basis of the compensated sensor output signals and the temperature sensor output signals whether the micro-electromechanical sensor is free of contamination or has contamination.

In one embodiment of the method, the method comprises the step of generating the control signals for controlling the heater.

The control signals are generated, for example, by the electronic circuit. For example, the control signals are generated by a control device provided externally to the sensor module.

FIG. 2 shows a system 201 for detecting contamination of a micro-electromechanical sensor 207 of a sensor module 205, comprising:
a heater 203 and
a sensor module 205, the sensor module 205 comprising:
a micro-electromechanical sensor 207 and
a temperature sensor 209 arranged at a distance from the heater 203 and from the micro-electromechanical sensor 207, wherein the system 201 is configured to carry out all steps of the method according to one of the above-described embodiments.

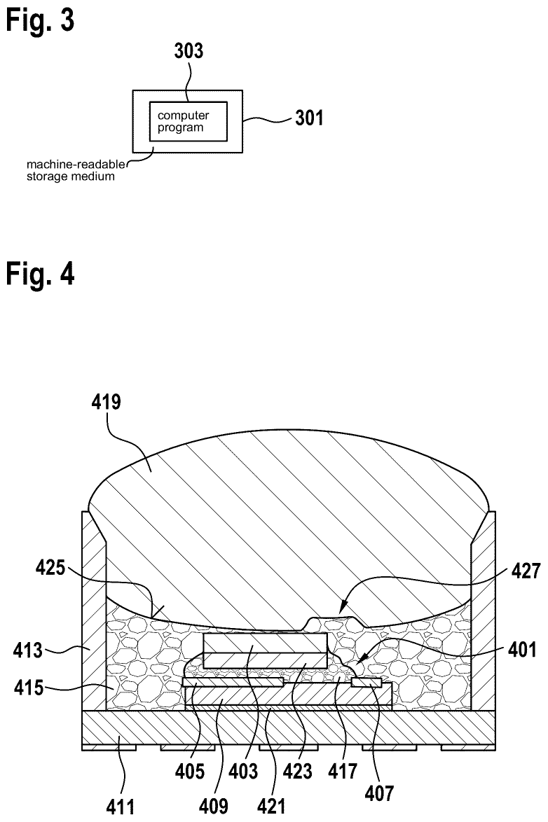

FIG. 3 shows a machine-readable storage medium 301 on which a computer program 303 is stored. The computer program 303 comprises instructions which, when the computer program 303 is executed by a computer, cause the computer to carry out a method according to the first aspect.

FIG. 4 shows a sensor module 401 comprising a MEMS sensor 403 as well as a heater 405 and a temperature sensor 407 and an electronic circuit 409. The electronic circuit 409 is located on a base 411 of a housing 413 in which the sensor module 401 is arranged.

The housing 413 is filled with a gel 415 as an example of a protective material in such a way that a surface of the sensor 403 is covered with a thin layer of gel.

The sensor 403 is materially bonded to the electronic circuit 409 by means of adhesive 417.

In the exemplary representation shown in FIG. 4, the sensor 403 has contamination 419. This can be detected according to the concept described here.

The electronic circuit 409 is arranged on a first substrate 421, which is arranged on the base 411 of the housing 413. The sensor 403 is arranged on a second substrate 423, which is glued to the electronic circuit 409 by means of the adhesive 417.

The base 411 of the housing 413 may be a third substrate, for example a silicon wafer.

Due to the surface tension of the gel 415, a surface profile of the gel along the sensor 403 substantially corresponds to a meniscus. The surface profile is denoted by reference sign 425. There is a region, indicated by reference numeral 427, in the surface contour 425 that deviates from the meniscus shape. This is in particular due to the fact that wires or electrical contacts for the sensor 403 are located within this region. These wires or electrical contacts are not shown for reasons of clarity.

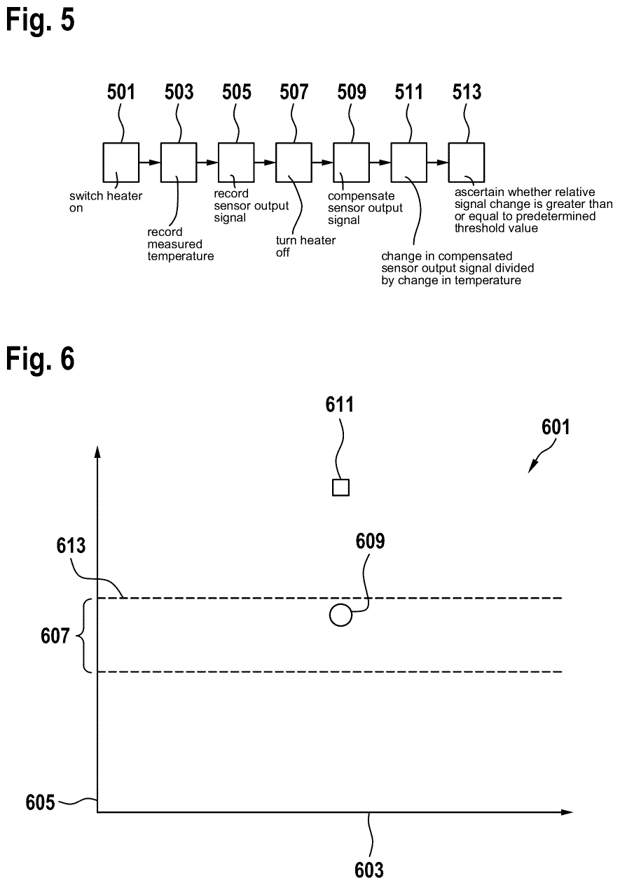

FIG. 5 shows a flow chart of a method according to the first aspect.

According to a step 501, the heater is switched on so that it generates heat. According to a step 503, a temperature measured by the temperature sensor is recorded. According to a step 505, a sensor output signal is recorded. In a step 507, the heater is turned off so that heating is stopped or terminated. According to a step 509, the sensor output signal is compensated with the temperature signal. According to a step 511, a change in the compensated sensor output signal is divided by a change in the temperature. In a step 513, it is ascertained whether a relative signal change is greater than or greater than or equal to a predetermined threshold value. If this is the case, it is determined that there is contamination on the sensor.

FIG. 6 shows a first graph 601 having an abscissa 603 and an ordinate 605.

The temperature change caused by the heater is plotted on the abscissa 603. The compensated sensor output signal change is plotted on the ordinate 605.

The reference sign 609 marks a point on the graph 601 where in this case the sensor is free of contamination, i.e. has no contamination. The reference sign 611 indicates a point on the graph 601 where the sensor has contamination.

A range 607 is defined, wherein it is determined that if the signal change lies within the range 607, the sensor is free of contamination. If the signal change lies above an upper limit 613, the sensor is determined to have contamination. The upper limit 613 of the range 607 is a predetermined threshold value in the sense of the description.

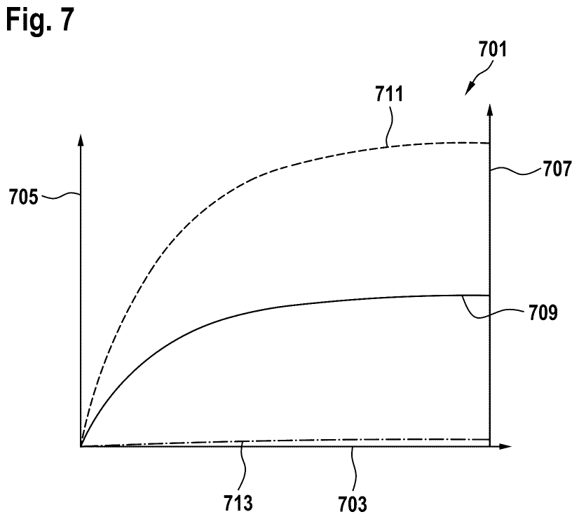

FIG. 7 shows a second graph 701 having an abscissa 703 and a left-hand ordinate 705 and a right-hand ordinate 707.

The time is plotted on the abscissa 703. The output signal of the sensor is plotted on the left-hand ordinate 705. The output signal of the temperature sensor is plotted on the right-hand ordinate 707.

The reference sign 709 shows the course of the temperature over time as measured by the temperature sensor. The reference sign 711 denotes an output signal of the sensor, wherein the sensor has no contamination. The reference sign 713 denotes an output signal of the sensor, wherein the sensor has contamination.

In summary, the concept described here comprises in particular a sensor module having a MEMS sensor and a control module as an example of an electronic circuit, wherein the control module has an embedded heater, in particular a heating element. The control module also includes a temperature sensor, for example. The temperature measurement value of the temperature sensor is used to compensate the temperature-dependent signal of the sensor. The compensation assumes that the sensor and the control module have a very small temperature difference or temperature gradient. When the heater is switched on, the entire sensor heats up with a slight temperature gradient between the sensor and the control module. If there is additional thermal mass, such as contamination on the sensor, the temperature gradient between the two increases and the temperature compensation no longer works correctly. By comparing a change in the sensor output signal over the absolute temperature difference with the specified change over a comparable temperature range, it can be determined whether contamination is present or not. This is especially useful for sensors that come into contact with external media, such as media-resistant sensors with a gel coating on the sensor. If the gel surface is sufficiently thin, the contamination will still have a significant impact on the thermal gradient between the sensor and the control module. Especially when used in an environment where the sensor may come into contact with a liquid, such as water, this can be used to determine whether the sensor has already dried out or whether the signal is still influenced by the water on top of the sensor.

According to one embodiment, a sensor module comprises the MEMS sensor, which can also be referred to as a measuring sensor, for measuring a physical quantity. The sensor module, for example, includes the control module. For example, the control module and the MEMS sensor are arranged within a housing. For example, the measuring sensor, i.e. the sensor, and the control module can be combined in one physical element or can be two separate elements connected to each other in the housing. Furthermore, a heater is provided, which can also be referred to as a heating module, which can be arranged, for example, either in the separate control module, in the housing or outside the sensor near the sensor. For example, the position of the heater is chosen so that in the absence of contamination the temperature gradient between the measuring sensor, i.e. the sensor, and the temperature sensor is minimal during the heating phase. For example, the position of the heater is chosen so that in the case of contamination, a maximum temperature gradient is created between the sensor and the temperature sensor.

For example, the sensor and the control module are housed in two different elements stacked on top of each other. In this case, the control module is located for example at the bottom of the housing and the sensor is located for example on top of the control module. The temperature sensor, for example, is located in the control module, as is the heating element, for example. For example, a thin layer of gel is placed over the sensor to allow possible contaminants to get close to the sensor. This results in very different temperature gradients between the sensor and the control module when contamination is present.

The concept described here includes in particular a method in which the, in particular embedded, heating module, i.e. the heater, is used to increase the temperature of the entire sensor with a particular quantity of thermal energy. This leads to a rise in the temperature of the sensor. The temperature is measured with the temperature sensor during the heating period. At the same time, the output signal of the sensor is recorded. The output signal is temperature-dependent and is therefore compensated, for example, with the temperature measurement value according to a predefined compensation formula. The maximum expected change in the output signal due to the induced temperature change is specified. If there is a marked temperature gradient between the sensor and the temperature sensor, the compensation will not work properly and the compensated output signal of the sensor, i.e. the compensated sensor output signal, will be in error.

This behavior is used for detecting contamination of the sensor. If contamination is present, the additional thermal mass of the contamination on the sensor will result in a greater temperature gradient between the sensor and the temperature sensor, which in turn will result in increased error. In this case, the change in the temperature-compensated output signal of the sensor over the temperature exceeds a specification and it can therefore be determined that the sensor has contamination.

In summary, the present invention relates in particular to a method for detecting contamination of a micro-electromechanical sensor of a sensor module using a heater, wherein the sensor module has a temperature sensor arranged at a distance from the heater and from the micro-electromechanical sensor. For example, it is provided that the sensor is heated by the heater, which is measured by the temperature sensor. Furthermore, physical quantities are measured, for example, by the sensor at different times. The measured physical quantities are compensated, for example, on the basis of the temperatures measured at the different times, wherein it is ascertained, for example, on the basis of the compensated physical quantities and the temperature difference between the different times, whether the micro-electromechanical sensor is free of contamination or has contamination.

What is claimed is:

1. A method for detecting contamination of a micro-electromechanical sensor of a sensor module using a heater, wherein the sensor module has a temperature sensor arranged at a distance from the heater and from the micro-electromechanical sensor, the method comprising the following steps:
outputting control signals for controlling the heater so that the heater generates thermal energy to heat the micro-electromechanical sensor;
receiving sensor output signals representing physical quantities measured by the micro-electromechanical sensor at different times during the generation of the thermal energy by the heater, and temperature sensor output signals representing temperatures measured by the temperature sensor at the different times during the generation of the thermal energy by the heater;
compensating the sensor output signals based on the temperature sensor output signals to generate compensated sensor output signals representing the compensated physical quantities measured at the different times; and
ascertaining based on the compensated sensor output signals and the temperature sensor output signals whether the micro-electromechanical sensor is free of contamination or has contamination.

2. The method according to claim 1, wherein the ascertaining of whether the micro-electromechanical sensor is free of contamination or has contamination is carried out based on a change in the compensated sensor output signals in relation to a change in the temperature sensor output signals.

3. The method according to claim 2, wherein the change in the compensated sensor output signals is correlated with the change in the temperature sensor output signals, including dividing, in order to ascertain a correlated relative change in the compensated sensor output signal, wherein based on the correlated relative change in the compensated sensor output signal, it is ascertained whether the micro-electromechanical sensor is free of contamination or has contamination.

4. The method according to claim 3, wherein the correlated relative change in the compensated sensor output signal is compared with a predetermined change threshold value, wherein, based on the comparison, it is ascertained whether the micro-electromechanical sensor is free of contamination or has contamination.

5. The method according to claim 1, wherein after a target temperature and/or a target temperature difference relative to a temperature for starting the heating is reached, control signals for controlling the heater are output so that the heater stops generating thermal energy for heating the micro-electromechanical sensor.

6. The method according to claim 1, wherein a calibration process is carried out when the micro-electromechanical sensor element is free of contamination, wherein the calibration process includes outputting control signals for controlling the heater so that the heater generates thermal energy for heating the micro-electromechanical sensor, and wherein the calibration process includes receiving sensor output signals representing physical quantities measured by the micro-electromechanical sensor at different times during the generation of the thermal energy by the heater and temperature sensor output signals representing temperatures measured by the temperature sensor at the different times during the generation of the thermal energy by the heater, and wherein the calibration process includes compensating the sensor output signals based on the temperature sensor output signals to generate compensated sensor output signals, which represent the compensated physical quantities measured at the different times, and wherein the calibration process includes ascertaining one or more calibration parameters based on the compensated sensor output signals and the temperature sensor output signals, based on which it is ascertained after the calibration process has been carried out whether the micro-electromechanical sensor is free of contamination or has contamination.

7. The method according to claim 6, wherein the calibration process includes correlating a change in the compensated sensor output signals with a change in the temperature sensor output signals, including dividing, to ascertain a correlated relative, change in the compensated sensor output signal, wherein the calibration process includes setting the correlated relative change in the compensated sensor output signal as a predetermined threshold value as one of the one or more calibration parameters.

8. A system for detecting contamination of a micro-electromechanical sensor of a sensor module, the system comprising:
a heater; and
a sensor module, the sensor module including:
a micro-electromechanical sensor, and
a temperature sensor arranged at a distance from the heater and from the micro-electromechanical sensor; and
a device configured to detect contamination of the micro-electromechanical sensor, the device configured to:
output control signals for controlling the heater so that the heater generates thermal energy to heat the micro-electromechanical sensor,
receive sensor output signals representing physical quantities measured by the micro-electromechanical sensor at different times during the generation of the thermal energy by the heater, and
temperature sensor output signals representing temperatures measured by the temperature sensor at the different times during the generation of the thermal energy by the heater,
compensate the sensor output signals based on the temperature sensor output signals to generate compensated sensor output signals representing the compensated physical quantities measured at the different times, and
ascertain based on the compensated sensor output signals and the temperature sensor output signals whether the micro-electromechanical sensor is free of contamination or has contamination.

9. The system according to claim 8, which is configured such that a first temperature gradient, when the heater is switched on and when the micro-electromechanical sensor is free of contamination, between the temperature sensor and the micro-electromechanical sensor is smaller by at least a predetermined factor than a second temperature gradient, when the heater is switched on and when the micro-electromechanical sensor has contamination, between the temperature sensor and the micro-electromechanical sensor.

10. The system according to claim 9, wherein the predetermined factor lies in a closed interval of 10 to 100.

11. The system according to claim 8, wherein the micro-electromechanical sensor is covered with a protective layer having a thickness that lies in a closed interval of 1 μm to 100 μm.

12. The system according to claim 8, further comprising a first substrate having an electronic circuit including a first Si wafer.

13. The system according to claim 12, wherein the micro-electromechanical sensor includes a second Si wafer, wherein the second Si substrate is arranged at a distance from the first Si substrate and is materially bonded thereto by an adhesive.

14. The system according to claim 13, wherein the first Si substrate includes the temperature sensor.

15. The system according to claim 12, wherein the micro-electromechanical sensor is covered with a protective layer having a thickness that lies in a closed interval of 1 μm to 100 μm, and the system further comprises a housing with a base on which the first substrate is arranged, wherein the housing is filled with a protective material such that the micro-electromechanical sensor is covered with the protective layer.

16. A non-transitory machine-readable storage medium on which is stored a computer program for detecting contamination of a micro-electromechanical sensor of a sensor module using a heater, wherein the sensor module has a temperature sensor arranged at a distance from the heater and from the micro-electromechanical sensor, the computer program, when executed by a computer, causing the computer to perform the following steps:
outputting control signals for controlling the heater so that the heater generates thermal energy to heat the micro-electromechanical sensor;
receiving sensor output signals representing physical quantities measured by the micro-electromechanical sensor at different times during the generation of the thermal energy by the heater, and temperature sensor output signals representing temperatures measured by the temperature sensor at the different times during the generation of the thermal energy by the heater;
compensating the sensor output signals based on the temperature sensor output signals to generate compensated sensor output signals representing the compensated physical quantities measured at the different times; and
ascertaining based on the compensated sensor output signals and the temperature sensor output signals whether the micro-electromechanical sensor is free of contamination or has contamination.
